(19) United States
(12) Patent Application Publication
(10) Pub. No.: US 2008/0186211 A1
(43) Pub. Date: Aug. 7, 2008

(54) METHOD AND APPARATUS FOR TEXT ENTRY OF TONE MARKS

(75) Inventor: ROBERT M. HARMAN, PALO ALTO, CA (US)

Correspondence Address: MOTOROLA INC, 600 NORTH US HIGHWAY 45, W4 - 39Q, LIBERTYVILLE, IL, 60048-5343, US

(73) Assignee: MOTOROLA, INC., LIBERTYVILLE, IL (US)

(21) Appl. No.: 11/671,802

(22) Filed: Feb. 6, 2007

(51) Int. Cl. H03K 17/94

(52) U.S. Cl. 341/22

(57) ABSTRACT

A method and apparatus for entering text including tone marks and integral diacritics, such as Vietnamese, uses a compact keypad (110). The compact keypad has letters in alphabetical sequence, including letters with integral diacritics (142, 143, 146, 148) in the same order as they arrive in the Vietnamese alphabet series. The five tone marks (154,155,157,158,159) are positioned on five separate keys (124, 125, 127, 128, 129) of the compact keypad (110). The apparatus has an associated method (300) where a processor determines if a previous keypress represents a neutral vowel (350) and modifies the neutral vowel with a tone mark 360 if a current keypress has an associated tone mark.

### FIELD OF THE INVENTION

The present invention relates generally to text entry using a keypad and more particularly to text entry for languages with a wide variety of characters.

### BACKGROUND

Asian languages, such as Chinese, Thai, Tsat, and Vietnamese, are tonal languages. This means that the pitch and tonal contour of a word may distinguish it from other words sharing the same string of phonemes. In the Vietnamese language, there are six different tones. In the modern Roman-alphabet orthography for Vietnamese, tones are indicated by annotation of a syllable's core vowel with a tone mark; the vowel may be neutral (no tone mark), or may carry any one of the following tone marks: acute accent, tilde, grave accent, hook above, or dot below. The five tone marks can be combined only with vowels and affect the meaning of the word. For example, [symbol] ây” in Vietnamese means “here” in English and [symbol] y” in Vietnamese means “there” in English. The difference between the two words is a tone mark (acute accent) on “â” in the latter word. Another example is “kia” in Vietnamese which means “there” in English and “kia” in Vietnamese which means “yonder” in English. The difference between the two words is a tone mark (grave accent) on “i” in the latter word. In the Vietnamese language, only the vowels can be altered using the tone marks. There are twelve neutral vowels (A \check{A} Â E Ê I O Ô [symbol] U [symbol] Y) in the Vietnamese language and five tone marks that can be used to modify these vowels.

Furthermore, in the Vietnamese language, there are 29 letters in the alphabet series as opposed to 26 letters in the English alphabet series. These letters are (A \check{A} Â B C D [symbol] E Ê G H I K L M N O Ô [symbol] P Q R S T U U′ V X Y), which have lower case versions as well as the upper case listed. Seven of these 29 letters (\check{A} Â [symbol] Ê Ô [symbol] ) have what Applicant will call integral diacritics. In other words, while they look like standard English letters with a mark, the mark indicates that they are, in fact, completely different letters, representing different phonemes from the unmarked form. Analogously, E and F in the English alphabet series may look very similar, but they represent very different sounds. As an example of the Vietnamese letters with integral diacritics, there are three letters that look like variants of “A” (A \check{A} Â) but they are all different from each other just as A is different from E in English.

So, with 17 consonants plus 12 vowels that may have any of 6 tones, there are a great variety of characters in the Vietnamese language. There are in all seventeen upper case consonant characters (B C D [symbol] G H K L M N P Q R S T V X), seventeen lower case consonant characters (b c d [symbol] g h k l m n p q r s t v x), twelve upper case neutral vowel characters (A \check{A} Â E Ê I O Ô [symbol] U [symbol] Y), twelve lower case neutral vowel characters (a \check{a} â e ê i o ô [symbol] u [symbol] y), twelve upper case acute vowel characters (Á [symbol] É [symbol] Í Ó [symbol] Ú [symbol] Ý), twelve lower case acute vowel characters (á [symbol] é [symbol] í ó [symbol] ú [symbol] ý), twelve upper case grave vowel characters (Á [symbol] É [symbol] Í Ó [symbol] Ú [symbol] Ý), twelve lower case grave vowel characters (á [symbol] é [symbol] í ó [symbol] ý), [symbol] twelve upper case tilde vowel characters (Ã [symbol] \tilde{E} [symbol] Ĩ Õ [symbol] Ũ [symbol] \tilde{Y}), twelve lower case tilde vowel characters (ã [symbol] \tilde{e} [symbol] ĩ õ [symbol] ũ [symbol] \tilde{y}), twelve upper case hook above vowel characters ( [symbol] [symbol] ) twelve lower case hook above vowel characters ( [symbol] [symbol] ), twelve upper case dot below vowel characters ( [symbol] [symbol] [symbol] ), and twelve lower case dot below vowel characters ( [symbol] [symbol] [symbol] ). This all produces an extremely wide (89 character) character set for the Vietnamese language not including Roman letters not used in the Vietnamese alphabet series (F, J, W, Z), punctuation, and other symbols. Each of these eighty nine characters is generally implemented in a processor using associated codepoints. These codepoints are assigned according to different standards, such as Unicode and Vietnamese Standard Code for Information Interchange (VISCII). Codepoints are the numbers that a processor stores in memory for the character with which the codepoint is associated. The processor works on the codepoints and not on the characters.

FIG. 4 shows an example of Unicode codepoints for Vietnamese vowel letters in both upper and lower cases with three different variations of tones. The block 410 shows Unicode codepoints for vowels with the neutral tone mark (i.e., without any tone mark). The block 420 shows Unicode codepoints for vowels with the acute tone mark. The block 430 shows Unicode codepoints for vowels with the grave tone mark.

In block 410, column 412 shows Unicode codepoints for the upper case vowel characters without any tone mark in column 416, and column 414 shows Unicode codepoints for the lower case vowel characters without any tone mark in column 418 (i.e., with the neutral tone mark). For example, the Unicode codepoint for “A” is [0041]. In block 420, column 422 shows Unicode codepoints for the upper case vowel characters with the acute tone mark in column 426, and column 424 shows Unicode codepoints for the lower case vowel characters with the acute tone mark in column 428. In block 430, column 432 shows Unicode codepoints for the upper case vowel characters with the grave tone mark in column 436, and column 434 shows Unicode codepoints for the lower case vowel characters with the grave tone mark in column 438. Unicode also includes codepoints (425, 435) for the tone marks (For example,

for the acute tone mark and [0300] for the grave tone mark). For example, “Á” can be stored by the processor using two codepoints [0061] and [0301], i.e., the first codepoint for “A” and the second codepoint for the acute tone mark. As a variant, “Á” can also be stored by the processor using a single codepoint [00C1].

FIG. 5 shows an example of Unicode codepoint for Vietnamese vowel letters in both upper and lower cases with another three variations of tones. In block 510, column 512 shows Unicode codepoints for the upper case vowel characters with the hook above tone mark in column 516, and column 514 shows Unicode codepoints for the lower case vowel characters with the hook above tone mark in column 518. In block 520, column 522 shows Unicode codepoints for the upper case vowel characters with the tilde tone mark in column 526, and column 524 shows Unicode codepoints for the lower case vowel characters with the tilde tone mark in column 528. In block 530, column 532 shows Unicode codepoints for the upper case vowel characters with the dot below tone mark in column 536, and column 534 shows Unicode codepoints for the lower case vowel characters with the dot below tone mark in column 538. Unicode also includes codepoints (515, 525, 535) for the tone marks (For example, [0309] for the hook above tone mark, [0303] for the tilde tone mark, and [0323] for the dot below tone mark). For example, [symbol] can be stored by the processor using two codepoints [0061] and [0309], i.e., the first codepoint for “A” and the second codepoint for the hook above tone mark. As a variant, [symbol] can also be stored by the processor using a single codepoint [1EA2].

Full keyboards are difficult to implement on small devices, such as mobile phones. Therefore, compact keypads have multiple letters assigned to each key. The multi-tap method is commonly used for text entry on devices with compact keypads, such as mobile telephones. Multi-tap requires one or more key presses to enter each desired letter. Though relatively inefficient, new methods based on multi-tap have been shown to increase users' text entry efficiency, particularly for keypads based on the 26 characters of the English alphabet series. However, for Asian languages like Vietnamese, multi-tap text entry can be exceedingly arduous.

Getting around keypad limitations for text entry of languages with many tone marks and many letters like Vietnamese is quite challenging. Existing Vietnamese text entry compact keypads place all five tone marks on a single key. (The neutral tone is indicated by an absence of a tone mark.) However, putting all five tone marks on a single key (e.g., a key representing the number 0) results in longer disambiguation times. For example, if a user wants to enter a letter with a “dot below” tone mark, then he will have to press a key one or more times to access the letter and then press a “0” key five times if the order of the tone marks on key number 0 is the standard “acute” then “grave” then “tilde” then “hook above” and then “dot below”. As a result, a user has to perform at least six key presses to get the desired character with a tone mark. The Vietnamese tone marks are also not explicitly displayed on compact keypads. As a result, users who benefit from explicit tone demarcations are likely to be confused.

Therefore, there is a need for a new or improved method or apparatus for entering text associated with a language like Vietnamese having inventories of characters plus tone marks exceeding the number keys available on an input device. The various aspects, features and advantages of the disclosure will become more fully apparent to those having ordinary skill in the art upon careful consideration of the following drawings and accompanying Detailed Description

### BRIEF DESCRIPTION OF THE FIGURES

The accompanying figures where like reference numerals refer to identical or functionally similar elements throughout the separate views and which together with the detailed description below are incorporated in and form part of the specification, serve to further illustrate various embodiments and to explain various principles and advantages all in accordance with the present invention.

FIG. 1 shows an example of an electronic device with a display and compact keypad in accordance with some embodiments of the invention;

FIG. 2 shows a block diagram of the electronic device shown in FIG. 1 in accordance with some embodiments of the invention;

FIG. 3 shows a flow chart of a method for entering text using multi-tap text entry in accordance with some embodiments of the invention;

FIG. 4 shows an example of Unicode codepoints for Vietnamese vowels in both upper and lower cases with three different variations of tones.

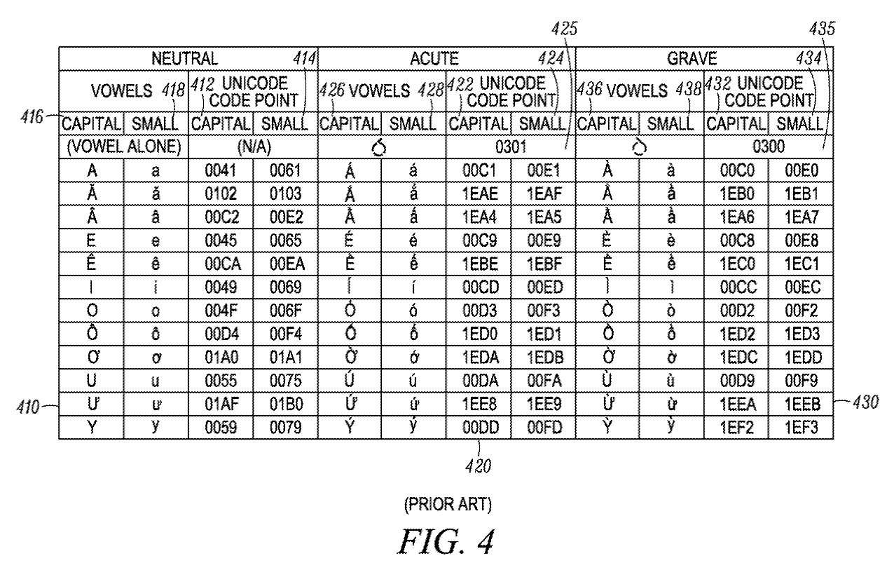

FIG. 5 shows an example of Unicode codepoints for Vietnamese vowels in both upper and lower cases with another three variations of tones.

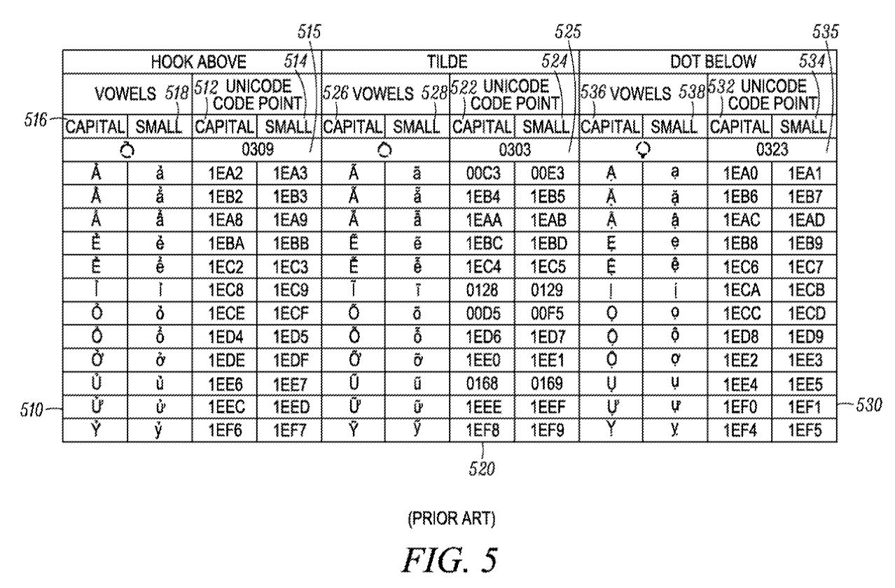

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

### DETAILED DESCRIPTION

Before describing in detail embodiments that are in accordance with the present invention, it should be observed that the embodiments reside primarily in a combination of method steps and apparatus components for a compact keypad layout for tonal languages like Vietnamese. All the tone marks are not assigned to a single key but are distributed over a plurality of keys. Accordingly, the apparatus and method components have been represented where appropriate by conventional symbols in the drawings, showing only those specific details that are pertinent to understanding the embodiments of the present invention so as not to obscure the disclosure with details that will be readily apparent to those of ordinary skill in the art having the benefit of the description herein.

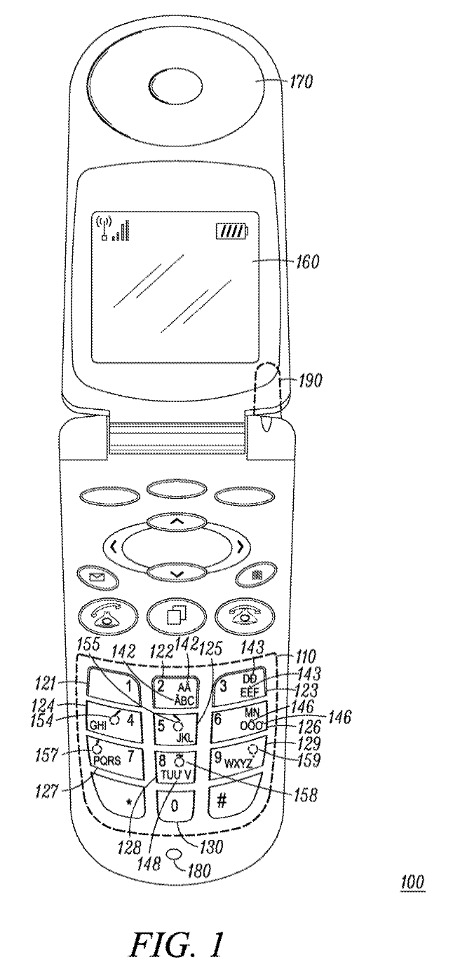

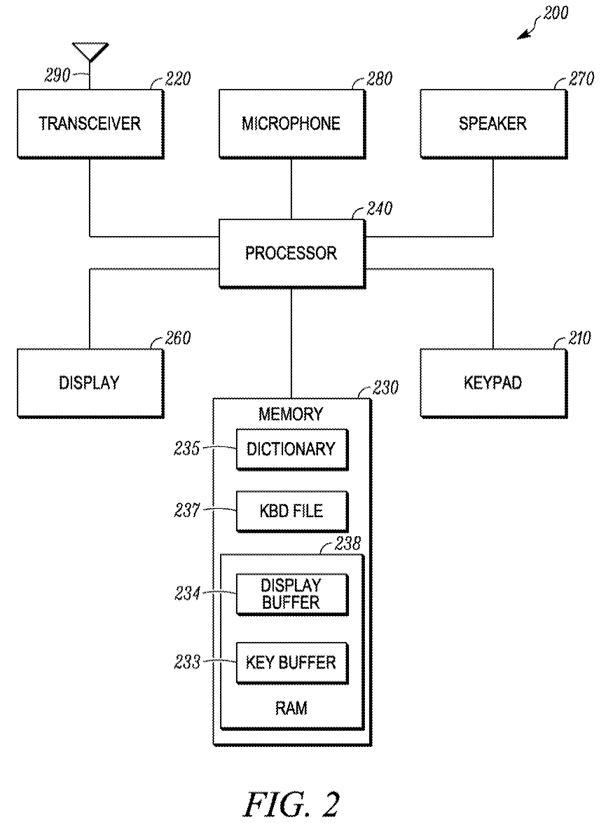

FIG. 1 shows an example of an electronic device 100 with a compact keypad 110, a display 160, a speaker 170, a microphone 180, and an antenna 190. The compact keypad 110 has letters in alphabetical sequence, including characters with integral diacritics, in the same order as they arrive in the Vietnamese alphabet series. Non-integral diacritics in the Vietnamese language, which are the five tone marks, are positioned on five separate keys of the compact keypad. The electronic device 100 also includes various processors, memory, and other electronic components as shown in FIG. 2. The electronic device 100 is shown as a mobile phone. Alternate electronic devices can be landline telephones, cordless telephones, personal digital assistants (PDAs), pagers, laptop computers, desktop computers, video game consoles, remote controllers, and other electronic devices that enable text entry using compact keypads.

The compact keypad 110 of the electronic device 100 shown has ten number keys 121, 122, 123, 124, 125, 126, 127, 128, 129, 130 of which eight are associated with Vietnamese letters and tone marks. For example, “2” key 122 shows the letters A, \check{A}, Â, B, and C in the Vietnamese alphabet series. Although the letters are explicitly shown on the key only in uppercase, both uppercase and lowercase characters associated with the letters A, \check{A}, Â, B, and C can be entered using the “2” key 122. The letters A B C are common to the English language. The letters \check{A} Â 142 as explained in the Background include integral diacritics and are letters in the Vietnamese alphabet series just as A, B, and C are letters in the Vietnamese alphabet series.

In accordance with a multi-tap text entry mode, if the “2” key 122 is pressed once, A is displayed on the screen. When the key 122 is pressed two times before a time out occurs between presses, \check{A} is displayed on the screen. When the key 122 is pressed three times without a time out occurring between any of the presses, Â is displayed on the screen. When the key 122 is pressed four times before a time out occurs between presses, B is displayed on the screen. When the key 122 is pressed five times before a time out occurs, C is displayed on the screen. For the “3” key 123 and the “6” key 126, the same pattern for the sequence of display for different letters associated with the key is followed in multi-tap text entry mode, because they are associated with letters that correspond to letters in the English alphabet series and also Vietnamese letters with integral diacritics. These keys 122, 123, 126 are not associated with tone marks.

The “3” key 123 shows the letters D, [symbol] , E, Ê, and F of the Vietnamese alphabet series. The letters D E F are letters common to the English alphabet series. The letters [symbol] Ê 143 include integral diacritics. Although the letter F is not used in the Vietnamese language, it is incorporated in the keypad layout to enable users to type in foreign names and words. Similarly, the letters J, W, and Z are not used in the Vietnamese language but are still incorporated in the keypad layout for the same reason. Each of the letters associated with the “3” key 123 can be displayed using a multi-tap text entry mode as explained previously.

The “6” key 126 shows the letters M, N, O, Ô, and [symbol] . The Vietnamese letters M N O are common to letters in English alphabet series. The letters Ô [symbol] 146 include integral diacritics in the Vietnamese alphabet series. If the “6” key 126 is pressed once, M is displayed on the screen. When the key 126 is pressed two times before a time out occurs between them, N is displayed on the screen. When the key 126 is pressed three times without a time out occurring between any of the keypresses, O is displayed on the screen. When the key 122 is pressed four times without a time out occurring, Ô is displayed on the screen. When the key 126 is pressed five times without a time out occurring, [symbol] is displayed on the screen.

Other keys 124, 125, 127, 128, 129 are associated not only with letters similar to English letters and Vietnamese letters with integral diacritics, but also with tone marks. The “4” key 124 shows the letters G, H, I, which are similar to letters in English alphabet series, and the acute tone mark 154. The “5” key 125 is associated with the letters J, K, L, which are similar to corresponding English letters, and the grave tone mark 155. The “7” key 127 is associated with the letters P, Q, R, S, which are similar to corresponding English letters, and the hook above tone mark 157. The “8” key 128 is associated with the letters T, U, V which are similar to corresponding English letters, integral diacritic letter [symbol] 148, and tilde tone mark 158. The “9” key 129 is associated with letters W, X, Y, Z and the dot below tone mark 159. The compact keypad 110 may also support user input of special symbols such as periods, spaces, punctuation marks, and the like.

The compact keypad 110 shown in FIG. 1 is but one implementation that is available which has more than one key associated with a tone mark. Variations include one key associated with two tone marks and another key associated with three tone marks, one key associated with two tone marks, another key associated with one tone mark and another key associated with two tone marks, one key associated with four tone marks and another key associated with one tone mark, etc. Aside from a single key being associated with all the tone marks, all the other variations are possible. Additionally, tone marks may be assigned to different keys (e.g. keys “1”-”5” rather than keys “4”, “5”, “7”, “8”, “9”).

The sequence for display is different for the keys 124, 125, 127, 128, 129 with associated tone marks from the keys 122, 123, 126 without associated tone marks. For example, if the “8” key 128 is pressed once, then this action will not necessarily display a letter T. Instead it will first check whether the character entered immediately preceding to this keypress is a neutral vowel.

In case the earlier entered character is not a neutral vowel, the first time the “8” key 128 is pressed, T is displayed on the screen next to the earlier entered character. If the key 128 is pressed again before a time out occurs, the T is replaced with a U. If the key 128 is pressed three times before time out occurs and the earlier entered character is not a neutral vowel, [symbol] is eventually displayed. If the key 128 is pressed four times before time out occurs and the earlier entered character is not a neutral vowel, V is displayed. Further keypresses will cycle through the T, U, [symbol] V character sequence in a modulo fashion.

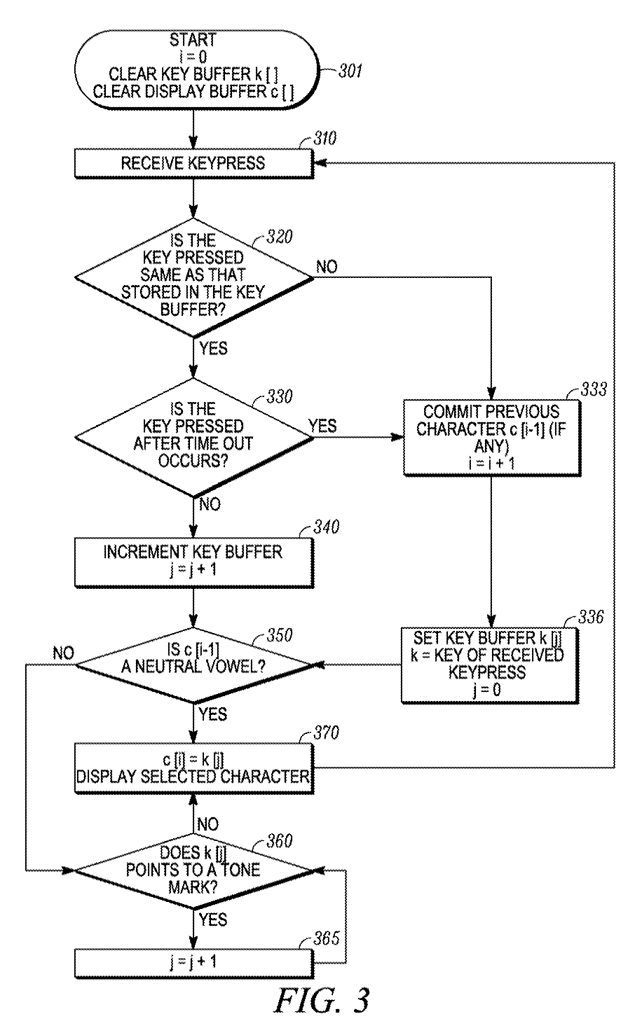

In the case where a neutral vowel immediately precedes the keypress, the neutral vowel is replaced by the vowel plus the associated tone mark (e.g., the vowel with a tilde tone mark). If the “8” key 128 is pressed two times before a time out occurs between keypresses, and the earlier entered character is a neutral vowel, then the first time the “8” key 128 is pressed, the entered vowel character is altered with the tilde tone mark 158 and the second time the “8” key 128 is pressed (before a time out occurs), the vowel character reverts back to neutral form and a letter T is displayed after the neutral vowel. Further keypresses of the “8” key 128 without an intervening timeout will continue through the remainder of the character cycle (e.g., U, [symbol] V), and yet more keypresses will return to the tilde mark on the preceding neutral vowel and then the character cycle again (e.g., T, U, [symbol] V). This is further explained in detail with reference to FIG. 3.

FIG. 2 shows a block diagram of the electronic device shown in FIG. 1. The block diagram 200 of the electronic device 100 includes a keypad 210, a microphone 280, a speaker 270, a display 260, an antenna 290, a transceiver 220, a processor 240, and a memory 230. In this example, the keypad 210 is the compact keypad 110 used for text entry in Vietnamese language. The display 260 shows the letter associated with keypresses on the keypad 210 as well as icons and messages and any previously entered letters. The microphone 280 is responsible for converting received audio signals into electrical signals for transmission, and the speaker 270 is responsible for converting electrical signals into audio signals. These signals are received and transmitted through the antenna 290. The transceiver 220 combines the transmission and the reception capabilities of the electronic device 100. The processor 240 is coupled to all the other parts of the electronic device.

The memory 230 is used to store temporary and permanent information. The memory includes a KBD file 237 (keyboard file) that contains and represents all the characters for each key on the keypad. For example, for key “2”, KBD file 237 contains 2[0] representing A, 2[1] representing B, 2[2] representing C, 2[3] representing \check{A}, and 2[4] representing Â. Similarly, for key “4”, KBD file 237 contains 4[0] representing the acute tone mark, 4[1] representing G, 4[2] representing H, and 4[3] representing I. The memory includes a display buffer 234 within a RAM 238. The processor 240 uses the display buffer 234 (c[ ]) to store the codepoints of all the characters that are at any time displayed on the screen and are already committed and also the codepoint for the most recent keypress (denoted by c[i]) which is generally not committed. The very first character of the text entry is represented by c[0], the second by c[1], and so on.

A key buffer 233 is also contained within the RAM 238. When a new key is pressed for the first time, the key buffer is set to that particular key's first element k[0] via a pointer. As that particular key is repeatedly pressed before a timeout occurs, the pointer scrolls through the options in a modulo fashion (i.e., k[1], k[2], and so on back to k[0]) in the KBD file 237. As a result, the key buffer represents the currently-selected character for the key that was just pressed. The memory 230 includes a dictionary 235 as well. The dictionary stores Vietnamese language words and these words are retrieved from the dictionary in a predictive text entry mode or a spell check mode.

In general, there are two text entry modes—multi-tap text entry mode and predictive text entry mode. FIG. 1 is explained taking the multi-tap text entry mode as the active text entry mode. In multi-tap text entry mode, the user presses a particular key a number of times to reach the desired letter. In predictive text entry mode, words are entered by using a single keypress for each letter of the word instead of multiple keypresses for each letter of the word as in multi-tap text entry mode. Software analyzes the keypress sequence and looks up all the possible words corresponding to the sequence of keypresses in the dictionary 235 and displays them on the screen. As the predictive software gains familiarity with the words and phrases the user commonly uses, it speeds the process by offering the most frequently used words first and then allows the user to access other choices with one or more presses of a predefined key such as a soft key or a navigation key.

In predictive text entry mode, two issues arise when associating all the tone marks on a single key. First, if the user presses a sequence of keys that includes the single tone mark key, the software will return all the possible words including all possible tone mark variations. If a given phonemic syllable exists with more than one tone—as is extremely common—there will automatically be multiple candidates created when a single tone mark key is pressed, because the same syllable must appear with the vowel marked with each applicable tone. By assigning tone marks to more than one key, the number of possible words can be reduced because not all tone marks will be among the candidates. Second, there is also a problem of finding a key to devote to the tone marks, because the designer may want to use the few keys other than the 2-9 number keys for things like punctuation, mode switching (e.g., among number entry, symbol entry, multitap entry, predictive text entry, and other entry methods), shift (e.g., capital letters), space, and so on. Hence, assigning tone marks to more than a single key and distributing them over the 2-9 number keys also helps to enhance the capability of the predictive text entry mode.

There are at least two ways to represent a vowel with a tone mark using codepoints. For example, the user wants to enter the word “ [symbol] ” using predictive text entry mode and the processor is using Unicode codepoints. The processor can store a dictionary entry for [symbol] y” as either four codepoints or three codepoints. Using four codepoints, the Unicode representation of [symbol] y” is [0111, 00E2, 0301, 0079], where [0111] is the Unicode codepoint for [symbol] , [00E2] is the Unicode codepoint for [symbol] , [0301] is the Unicode codepoint for composible acute tone mark, and [0079] is the Unicode codepoint for “y”. A composible character is a character that can be combined with another character to produce a single, composite character. In this situation, composible characters include the five Vietnamese tone marks, which may be combined with any neutral vowel to create a tone marked vowel character.

As a variant to this four-codepoint storage method, the processor can store a dictionary entry for [symbol] y” as three codepoints [0111, 1EA5, 0079], where [0111] is the Unicode codepoint for [symbol] , [1EA5] is the Unicode codepoint for [symbol] , and [0079] is the Unicode codepoint for “y”.

By using a four codepoint dictionary representation that replaces a single tone marked vowel codepoint with the neutral vowel codepoint followed by a composible tone mark codepoint, a predictive text entry processor can more easily disambiguate keypad text entries; in most situations a separated tone mark dictionary representation, plus having tone marks distributed over multiple keys, will result in fewer words that satisfy a particular predictive text entry key sequence.

FIG. 3 shows a flow chart of a method 300 for entering text using multi-tap text entry mode. In Vietnamese language, the tone marks can be applied only to neutral vowels. Therefore, in multi-tap text entry mode, the processor has to determine whether the preceding character is a neutral vowel and if the current keypress has a tone mark associated with it. The method in FIG. 3 describes checking on the time out between two keypresses on the same key, checking if the last keypress represents a neutral vowel, and checking if the current keypress has an associated tone mark. Then depending upon all these conditions, the appropriate character is entered. For example, a character without an integral diacritic, a character with an integral diacritic, or a composible tone mark character. The time outs are used to enter multiple letters associated with a single key sequentially (e.g., C A B) or to add a tone mark to a neutral vowel associated with the same key (e.g., Ũ).

The method starts in step 301 with the user entering the multi-tap text entry mode. As part of step 301, the key buffer k[ ] and the display buffer c[ ] are cleared. Then the user starts entering text by pressing keys. In step 310 the processor receives the first keypress. Then in step 320, the processor checks if the key pressed in step 310 is the same as the key represented in the key buffer. Because there is no key represented in the key buffer before a first keypress, step 320 determines that the key pressed during the first pass through step 310 is not the same as the key represented in the key buffer, and step 333 commits the character at c[i] in the display buffer. For this first keypress, there is no character at c[i] in the display buffer, so no character is actually committed. If there were a previous character, the pointer “i” would be advanced to commit that character. Now in step 336 the processor sets the key buffer k[j], such that k is the key of the received keypress (e.g., 1, 2, 3, . . . , 9) and j is equal to zero. This sets the key buffer such that it represents the first character associated with the currently-pressed key from the most recent pass through step 310.

In step 350, the processor checks if the previous character is a neutral vowel (i.e., whether c[i−1] is a neutral vowel). Because there is no character c[i−1] for the first keypress, step 360 next determines if the key buffer k[0] set in step 336 currently points to a tone mark. If the key buffer currently points to a tone mark, step 365 increments the key buffer, so that the key buffer points to the next character associated with the pressed key.

For example, if the key “4” is currently pressed in step 310 and is the first keypress of a text entry, the processor will set the key buffer to 4[0]=acute accent in step 336 and increment the key buffer to 4[1]=G in step 365. Step 365 returns to step 360 until all the tone marks on that key are by-passed. For the keypad layout shown in FIG. 1, step 365 will occur a maximum of one time, because a maximum of one tone mark is assigned to any particular key. For embodiments that have more than one tone mark assigned to a single key, step 365 may occur multiple times in quick succession. Thus, steps 360 and 365 skip the tone marks on a currently pressed key when the earlier character (c [i−1]) is not a neutral vowel.

When step 360 determines that the key buffer k[j] does not point to a tone mark, in step 370 the processor enters the codepoint of the character in the key buffer k[j] as the current element in the display buffer c[i] and displays that particular selected character c[i] along with any previously committed characters in the display buffer.

Returning to step 310 for a second keypress, the processor next determines if the second keypress was on the same key as the key represented by the key buffer k[j]. If not, step 333 commits the previous character by advancing the pointer (i=i+1), such that the character previously at c[i] is now at c[i−1]. In this case, the character represented by the first keypress is now at c[i−1]. Step 336 sets the key buffer for the current keypress, which would be the second keypress.

In this second pass through the flow chart 300, step 350 checks to see if the previous character c[i−1] was a neutral vowel. If the previous character c[i−1] was not a neutral vowel, the processor advances through steps 360, 365 as previously described. If the previous character c [i−1] was a neutral vowel, step 370 sets the current character in the display buffer c[i] to the character represented by the key buffer k[j] and displays the selected character. If the character represented by the key buffer k[j] is a composible character representing a tone mark, the processor graphically combines the previous neutral vowel in the display buffer c[i−1] with the current tone mark in the display buffer c[i] to create a composite character on the display.

Returning to step 320 for the second keypress, if the second keypress was on the same key as the first keypress (as represented in the key buffer), step 320 follows the “YES” branch and step 330 determines if the key was pressed before a time out occurred. If the second keypress occurred after a timeout, step 333 commits the previous character (i=i+1) and goes on to step 336 which has previously been described. If the second keypress occurred before a time out, step 340 increments the key buffer (j=j+1), so that it now points to the next character on the same key. The flow then returns to step 350, which has been previously described. If at any point, the user runs off the end of the list of characters on any of the keys, the key buffer pointer “j” is reset to “0”, such that it again points to the first character or tone mark on that particular key.

The same process is followed as further keypresses are received. Although not shown, navigation keys may be used to move through the display buffer, and the backspace key may be used to delete one or more characters in the display buffer. The process is exited at any time whenever the user presses a key (or sequence of keys) that cause the electronic device to exit the multi-tap text entry mode. Whenever the user exits the process, the contents of the display buffer are passed to the application that originally started the text-entry process. For example, the user may be sending a message, creating a name for a phonebook entry, or creating the title of a calendar entry.

As a concrete example, if the user wants to enter the word [symbol] y” using multi-tap text entry mode, and the processor is using Unicode codepoints, the following steps will be followed for the word [symbol] y”. First of all, the user will enter the multi-tap text entry mode per step 301. The display buffer's counter is initialized (i=0). The user will then press the “3” key 123 shown in FIG. 1. In response to this, the processor 240 will receive the keypress 310 and then the processor 240 will check if the key pressed is same as in the key buffer according to step 320. Because it is the first keypress of the text entry, there is nothing in the key buffer or the display buffer at this point; as a result, the processor skips through step 333 and moves to step 336. In step 336, the key buffer k[j] is set such that “k” is “3” and “j” is “0”. The key buffer points to a “d” character. Step 350 notes that there is no previously entered character residing in c [i−1] (c[−1] is an invalid address), so c[i−1] cannot be a neutral vowel, and the processor advances to step 360. Step 360 notes that “d”, the character currently referenced by the key buffer, is not a tone mark, and the processor advances to step 370. In step 370 the codepoint for “d” is copied to the display buffer c[i] (currently c[0]) from the key buffer k[j], and “d” is shown in the first cell of the display.

Now the user will quickly press the “3” key 123 again. The processor 240 will receive the keypress in step 310 and check in step 320 if the key pressed is same as the key represented in the key buffer. The processor 240 establishes that the same key is pressed again, so the processor now moves to step 330 and determines if the key is pressed after a time out has occurred. The processor 240 establishes that the key is pressed before the time out and hence moves to step 340 and increments the key buffer (j=j+1) such that the key buffer now points to [symbol] In step 350, because there is still nothing in c[i−1], the processor again passes through step 360, noting that [symbol] is not a tone mark, and moves to step 370. In step 370, the codepoint for “d” is replaced with the codepoint for [symbol] in the display buffer c[0] and [symbol] is displayed.

The first letter of the word [symbol] y” is now displayed on the screen. Now the user presses the “2” key 122. The processor 240 will receive the keypress in step 310 and will now determine in step 320 if the key pressed is the same as that represented in the key buffer. The processor establishes that it is not the same, because the key buffer contained a character associated with the key “3” and the currently pressed key is “2”, so the processor now commits the previous character in step 333 ( [symbol] remains stored at c[0], and the counter i is incremented, i=i+1=1). Now the processor moves to step 336 and sets the key buffer k[j] to 2[0]=“a” as being the first character associated with the “2” key in the KBD file 237 shown in FIG. 2. Now the processor checks if the previous character c[i−1] is a neutral vowel in step 350. Because the previous character was [symbol] , the processor establishes that the previous character was not a neutral vowel and hence moves to step 360. Here, the processor 240 will check if the key buffer k[j] (i.e., “2[0]” here) points to a tone mark. Because the key buffer points to “a”, the processor establishes that the current key does not point to a tone mark, the processor moves to step 370 and inserts the codepoint ([0061] for Unicode codepoint) for “a” in the last element of the display buffer c[i] and displays the characters whose codepoints are in the display buffer (e.g., [symbol] a”).

The user will press the “2” key 122 again before time out occurs to scroll through the characters associated with that key. The processor will receive the next keypress 310 and check if the key pressed is the same as represented in the key buffer 320. The processor 240 establishes that the same key is pressed again, so the processor now moves to step 330 and determines if the key is pressed after a time out has occurred. The processor 240 establishes that the key is pressed before a time out and hence moves to step 340 and increments the key buffer (j=j+1) such that the key buffer now points to “\check{a}” in this case. The processor now moves to step 370 because step 350 determines that c[i−1] is not a neutral vowel and step 360 determines k[j] does not point to a tone mark. In step 370 the codepoint for “a” is replaced with the codepoint for “\check{a}” in the display buffer, and [symbol] \check{a}” is displayed.

Now the user will again press the “2” key 122 before time out occurs. The processor 240 will receive the next keypress 340 and check if the key pressed is the same as indicated in the key buffer 320. The processor 240 establishes that the same key is pressed again, so the processor now moves to step 330 and determines if the key is pressed after a time out has occurred. The processor 240 establishes that the key is pressed before the time out and hence moves to step 340 and increments the key buffer (j=j+1) such that the key buffer points to “â”. The processor moves to step 370 because steps 350 and 360 determine that c[i−1] is not a neutral vowel and k[j] does not point to a tone mark. In step 370 the codepoint for “\check{a}” is replaced with the codepoint [00E2] for “â” in the display buffer and [symbol] â” is displayed.

At this point, the display buffer 234 within the RAM 238 contains the Unicode codepoints [0111] and [00E2]. The display shows [symbol] â”. Now the user presses the “4” key 124 because the user wants to put the acute tone mark on the neutral vowel “â”. The processor 240 will receive the next keypress in step 310 and will now determine if the key pressed is same as that represented in the key buffer. The processor establishes that it is not same, because the key buffer represented a character associated with the key “2” and the currently pressed key is “4”, so the processor now commits the previous character in step 333 (“â” remains at c[1] and the cursor is moved forward by setting i=i+1=2). Now the processor moves to step 336 and sets the key buffer k[j] (e.g., “k” is set to “4” and “j” is set to “0”) such that it now points to the acute tone mark. Now the processor checks if the previous character (c[i−1]) is a neutral vowel 350. Because the previous character was “â”, the processor establishes that the previous character is a neutral vowel and hence moves to step 370. Here, the processor 240 will modify the “â” with the composible character “acute tone mark”, by entering the codepoint for the composible acute tone mark in the display buffer c[i] and displaying [symbol] .

Now the user should press the “9” key 129. The processor 240 will receive the next keypress 310 and will now determine if the key pressed is same as that represented in the key buffer 320. The processor establishes that it is not same, because the key buffer had the key “4” represented and the currently pressed key is “9”, so the processor now commits the previous character in step 333. In this implementation where a single codepoint represents a vowel having a tone mark, committing the previous character involves replacing the codepoint for “â” in c [1] with the codepoint for the tone-modified character [symbol] and leaving the counter i set to 2 (instead of advancing the counter i). An alternate implementation, where two codepoints are combined to represent a vowel having a tone mark, commits the previous character (a composible tone mark) by advancing the counter (i=i+1=3).

Now the processor moves to step 336 and sets the key buffer k[j] (e.g., k is set to “9” and “j” is set to “0”) and it points to the “dot below,” which is a tone mark. The processor checks if the previous character (c[i−1]) is a neutral vowel in step 350. Because the previous character was [symbol] , the processor establishes that the previous character was not a neutral vowel and hence moves to step 360. Here, the processor 240 will check in step 360 if the key buffer k[j] points to a tone mark. Because the key buffer k[j] currently points to the “dot below” tone mark, the processor moves to step 365 and increments the key buffer such that the key buffer now points to “w” (k[j]=9[1]). The processor now moves to step 370 and enters the codepoint for “w” in the display buffer at element c[i] and displays the characters whose codepoints are in the display buffer (e.g., [symbol] w”).

The user will press the “9” key 129 from FIG. 1 again before a time out occurs to cycle toward the letter “y” on the “9” key. The processor 240 will receive the next keypress in step 310 and determine that the same key is pressed again in step 320, so the processor now moves to step 330 and determines if the key is pressed after a time out has occurred. The processor 240 establishes that the key is pressed before the time out and hence moves to step 340 and increments the key buffer (j=j+1) such that the key buffer points to “x” now. The processor moves to step 370 because steps 350 and 360 determine that c[i−1] is not a neutral vowel and k[j] does not point to a tone mark. In step 370 the Unicode codepoint for “w” is replaced with the Unicode codepoint for “x” in the display buffer element c[i] and [symbol] x” is shown on the display.

Now the user will press the “9” key 129 again before a time out occurs. The processor will receive the next keypress in step 310 and will establish in step 320 that the same key was pressed again, The processor also determines that the key was pressed after a time out has occurred in step 330 and increments the key buffer (j=j+1) in step 340 such that the key buffer now points to “y”. The processor now moves to step 370 because steps 350 and 360 determine that c[i−1] is not a neutral vowel and k[j] does not point to a tone mark. In step 370 the Unicode codepoint for “x” is replaced with the Unicode codepoint for “y” in the display buffer at element c[i] and [symbol] y” is shown on the display.

The entire word [symbol] y” has been entered using nine keypresses (3, 3, 2, 2, 2, 4, 9, 9, 9). Now, the user chooses to store the entire text entry and exit the process. The display buffer c[ ] contains Unicode codepoints for the three characters [symbol] , [symbol] , and “y”. As the process is exited, these codepoints are passed to the application in use before the text-entry process began.

In the example given for entry of the word [symbol] y”, the display buffer stores one codepoint for the complete form of a vowel having a tone mark. As a variant, when a tone mark is committed in step 333, the two codepoint combination in the display buffer may be kept, by leaving the composible tone mark in c[i] and advancing the counter (i=i+1). In this case, the display buffer will, at the end of entry, contain four codepoints, for the characters [symbol] , “â”, composible acute accent, and “y”.

By associating tone marks with more than one key, a user can select a particular tone for a particular neutral vowel using only one keypress. If a letter is desired instead of putting a tone mark on the neutral vowel, the key is quickly pressed another time, and the tone mark disappears and the letter series associated with that key is accessed. The distributed-tone keypad also enhances the capability of a predictive text entry mode because it reduces the number of words associated with a particular sequence of keypresses. The method and keypad layout described can be applied not only to Vietnamese and other Asian tonal languages but also African tonal languages such as Yoruba and Igbo and other families of tonal languages.

In the foregoing specification, specific embodiments of the present invention have been described. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of present invention. The benefits, advantages, solutions to problems, and any element(s) that may cause any benefit, advantage, or solution to occur or become more pronounced are not to be construed as a critical, required, or essential features or elements of any or all the claims. The invention is defined solely by the appended claims including any amendments made during the pendency of this application and all equivalents of those claims as issued.

In this document, relational terms such as first and second, top and bottom, and the like may be used solely to distinguish one entity or action from another entity or action without necessarily requiring or implying any actual such relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “comprises . . . a” does not, without more constraints, preclude the existence of additional identical elements in the process, method, article, or apparatus that comprises the element.

We claim:

1. A method for text entry comprising:
receiving a first keypress;
displaying a first character associated with the first keypress;
receiving a second keypress;
determining if the first character is a neutral vowel;
modifying the first character with a tone mark, if the second keypress represents a tone mark.

2. A method of claim 1, wherein receiving a first keypress further comprises:
setting a key buffer to represent a character associated with the first keypress.

3. A method of claim 2, wherein displaying comprises:
entering a codepoint for a displayed character from the key buffer to a display buffer.

4. A method of claim 2, wherein receiving a second keypress further comprises:
checking if the second keypress is on a key represented by the key buffer.

5. A method of claim 4, wherein checking further comprises:
committing the first character, if the second keypress is not on the key represented by the key buffer.

6. A method of claim 4, wherein checking further comprises:
deciding if a time out occurs between the first keypress and the second keypress, if the second keypress is on the key represented by the key buffer.

7. A method of claim 6, wherein deciding further comprises:
committing the first character, if the time out occurs.

8. A method of claim 6, wherein deciding further comprises:
incrementing the key buffer, if no time out occurs.

9. A method of claim 6, wherein committing further comprises:
setting the key buffer to represent a character associated with the second keypress.

10. A method of claim 2, wherein determining further comprises:
ascertaining if the key buffer represents a tone mark, if the first character is not the neutral vowel.

11. A method of claim 9, wherein ascertaining further comprises:
bypassing all tone marks associated with the key represented by the key buffer.

12. A method of claim 1, wherein modifying further comprises:
graphically combining the neutral vowel with the tone mark to create a composite character on a display.

13. A keypad layout comprising:
a first key associated with a first tone mark; and
a second key associated with a second tone mark.

14. The keypad layout according to claim 13 comprising:
a third key associated with a third tone mark.

15. The keypad layout according to claim 14 comprising:
a fourth key associated with a fourth tone mark.

16. The keypad layout according to claim 15 comprising:
a fifth key associated with a fifth tone mark.

17. The keypad layout according to claim 13, wherein each tone mark is explicitly shown on an assigned key.

18. The keypad layout according to claim 17, wherein the first key explicitly shows the first tone mark.

19. The keypad layout according to claim 17, wherein the second key explicitly shows the second tone mark.

20. The keypad layout according to claim 13, wherein multiple letters from an alphabet series are assigned to a key.

21. The keypad layout according to claim 20, wherein a character with an integral diacritic is assigned to the key in an order in which the character arrives in the alphabet series.

22. The keypad layout according to claim 20, wherein the alphabet series is a Vietnamese alphabet series.
